(19) United States
(12) Patent Application Publication
(10) Pub. No.: US 2013/0001740 A1
(43) Pub. Date: Jan. 3, 2013

(54) HEAT SPREADER FOR THERMALLY ENHANCED FLIP-CHIP BALL GRID ARRAY PACKAGE

(75) Inventor: Yiyi Ma, Singapore (SG)

(73) Assignee: STMICROELECTRONICS PTE LTD., Singapore (SG)

(21) Appl. No.: 13/174,591

(22) Filed: Jun. 30, 2011

(51) Int. Cl. H01L 27/02; B32B 23/02

(52) U.S. Cl. 257/528; 428/192; 257/E27.009

(57) ABSTRACT

A heat spreader is provided for use with a thermally enhanced flip-chip ball grid array package. In the package, a semiconductor die is positioned front-side down on a package substrate, coupled thereto via solder balls. Passive devices can also be coupled to the substrate alongside the die. The heat spreader is positioned over the substrate and die, in thermal contact with the die. A projection in the center of the heat spreader makes contact with the back surface of the die via a thermal interface material, to draw heat from the die for improved cooling. The projection enables close contact with a thinned die while accommodating thicker passive devices positioned around the die on the substrate.

### BACKGROUND OF THE INVENTION

1. Technical Field

Embodiments of this disclosure are related to semiconductor packaging, and in particular to semiconductor packages that include heat sinks for passive cooling of a semiconductor die.

2. Description of the Related Art

As semiconductor packaging has evolved to accommodate the increasing complexity and miniaturization of semiconductor devices, a number of different packaging structures have been developed to meet various specifications. These include Ball Grid Array (BGA), Flip-Chip (FC), and Thermal Enhancement (TE).

In BGA, an array of solder balls is arranged on a bottom surface of the package. The ball grid array is aligned with a corresponding array of contact pads on the surface of a circuit board, and the assembly is heated until the solder of the balls melts and reflows to electrically and mechanically couple the package to the circuit board. In an FC structure, contact pads on the active face of a semiconductor die are directly coupled to another circuit structure, such as a laminate base of a chip package or a circuit board. This usually entails inverting the die to place the active face of the die against the other circuit structure, hence the name. The electrical connection is typically made via solder balls (i.e., BGA). A laminate base is generally used in applications where the grid of contact pads on the semiconductor die is at a finer pitch than the contact pads on the circuit board to which the die is to be attached. The laminate base has “landing pads” on its upper surface to receive the array of solder balls coupled to the pads of the die, which are coupled, via a redistribution layer, with corresponding pads on its lower surface that are arranged at a pitch corresponding to the array of pads on the circuit board. The lateral dimensions of the laminate are greater than those of the die to accommodate the coarser pitched array on its lower surface. Finally, in TE, a heat sink is incorporated into the package and thermally coupled to the semiconductor die to improve the thermal performance of the package.

FIGS. 1-4 show examples of thermally enhanced flip-chip ball grid array (TEFCBGA) packages, according to known art. FIG. 1 is a partially cut-away perspective view of a first TEFCBGA package 100, shown in FIG. 2 in a diagrammatical side view. The package 100 includes a laminate substrate 102 with a back face 103 on which a semiconductor die 104 is mounted in a flip-chip arrangement and coupled to the laminate via a ball grid array (BGA) 106. A heat spreader 108 is coupled to the substrate 102, and solder balls 110 are arranged in a BGA 107 on the front side of the substrate, for connection of the package 100 with a circuit board.

In the example shown in FIGS. 1 and 2, the heat spreader 108 comprises a stiffener 114 and a lid 116 attached to the substrate by a suitable adhesive. The thickness of the stiffener 114 is selected to be substantially equal to the spacing between the back surface of the laminate base 102 and the back surface 118 of the die 104, so that a front surface 115 of the lid 116 comes into close contact with the back surface 118 of the die 104. A thermal interface material, such as thermally conductive grease or adhesive, is positioned between the back surface 118 of the die 104 and the front surface 115 of the lid 116 to improve the transfer of heat from the die to the heat spreader 108.

Additional passive electronic devices 112, such as, e.g., resistors, inductors, and capacitors, can be mounted to the laminate base 102 around the die 104 in a space between the heat spreader 108 and the laminate 102. This can be very beneficial, especially where the passive devices are closely associated with the circuit on the die 104, as explained below.

In many systems, passive devices that are external to an integrated circuit die are required to establish selectable parameters of various circuits integrated into the circuit on the die. For example, such passive devices can be used to establish the frequency or range of an oscillator, the range of a filter, the value of a reference voltage, etc. In such cases, the die might have pairs of contact terminals that are to be coupled only to terminals of respective resistors or capacitors. In a standard arrangement, the passive devices would be mounted to a circuit board together with a semiconductor package, with circuit traces formed in or on the circuit board coupling terminals of the passive devices to corresponding contacts of the package. By mounting the passive devices inside the package, the connections between the die and the passive devices can be made internal to the package. This reduces the number of contacts between the package and the circuit board, and also reduces the number of components that are mounted to the circuit board.

Because the overall dimensions of the package 100 are determined by the pitch and number of contacts of the BGA 107 on the bottom of the package rather than the size of the die 104, the inclusion of the passive devices 112 in the package in otherwise unused space on the upper side of the laminate base does not appreciably increase the footprint of the package. Meanwhile, the circuit board to which the package 100 is to be attached does not need to carry those passive devices, and can therefore be made less complex and more compact.

FIG. 3 is a diagrammatic side view of a TEFCBGA package 120 that is in most respects similar to the package 100 of FIGS. 1 and 2. The package 120 includes a heat spreader 122 in which the stiffener and lid are integrated into a single element. The heat spreaders 108, 122 of FIGS. 1-3 can be made by a number of different processes and from a variety of materials. For example, they can be injection molded using a ceramic material having high thermal conductivity, or a metallic molding compound that is then sintered to remove binders and densify the part. They can also be machined from metal plates.

FIG. 4 is a diagrammatic side view of a TEFCBGA package 130 that is also substantially similar to the package 100 of FIGS. 1 and 2, except that the heat spreader 132 is a piece of sheet metal formed in a stamping process. The heat spreader 132 is typically made of copper, but can be any appropriate material, such as, e.g., aluminum. Copper is preferred because of its high thermal conductivity. Such spreaders are sometimes referred to a hat top covers or spreaders.

The heat spreaders 108, 122, 132 of FIGS. 1-4 function substantially identically. Heat generated by the die 104 during operation is transmitted via the thermal interface material to the heat spreader, which has a much greater surface area and is directly exposed to the ambient air. This enables the passive dissipation of more heat than would be possible if the die were in a more conventional package. In addition to improved thermal performance, the TEFCBGA packages of FIGS. 1-4 are substantially thinner than a conventional semiconductor package. Heat spreaders are commonly employed in applications where active cooling is impractical, such as in cell phones and other hand-held electronic devices.

### BRIEF SUMMARY

According to an embodiment, a heat spreader is provided, for use in semiconductor packages, that has a depth sufficient to receive passive devices therein, and that includes a projection extending from an inner face of the heat spreader to make thermal contact with a back surface of a semiconductor die.

According to an embodiment, a heat spreader is provided, including a rim formed around the perimeter of the heat spreader and having a rim face defining a first plane. A web having an inner face is coupled to and extends inward from the rim. A projection extends from the inner face of the web toward the first plane, and includes a projection face lying in a second plane parallel to the first plane.

The heat spreader can be formed by any of a number of processes, including stamping, fine blanking, injection molding of metallic or ceramic material, and machining of metallic blanks.

According to an embodiment, the heat spreader is included as part of a semiconductor package. The rim is sized to be coupled to the perimeter of a laminate base to which a semiconductor die is coupled. Passive devices are also coupled to the laminate base and completely enclosed with the die by the heat spreader. The die is thinned to less than 500 μm, and preferably less than 200 μm. As a result, the die is thinner than the passive devices. Accordingly, the projection face extends inward from the inner face of the web to make close thermal contact with the surface of the semiconductor die, while providing space around the die for the passive devices.

### BRIEF DESCRIPTION OF THE SEVERAL VIEWS OF THE DRAWINGS

FIGS. 1-4 show examples of TEFCBGA packages, according to known art. FIG. 1 is a partially cut-away perspective view of a first TEFCBGA package, shown in FIG. 2 in a diagrammatical side view.

FIGS. 3 and 4 are diagrammatical side view of respective TEFCBGA packages, according to known art.

FIG. 5 is a partially cut-away perspective view of a TEFCBGA package, according to an embodiment.

FIG. 6 is a diagrammatical side view of the package of FIG. 5.

FIG. 7 is a diagrammatical side view of a TEFCBGA package according to a second embodiment.

FIG. 8 is a diagrammatical side view of a TEFCBGA package according to a third embodiment.

### DETAILED DESCRIPTION

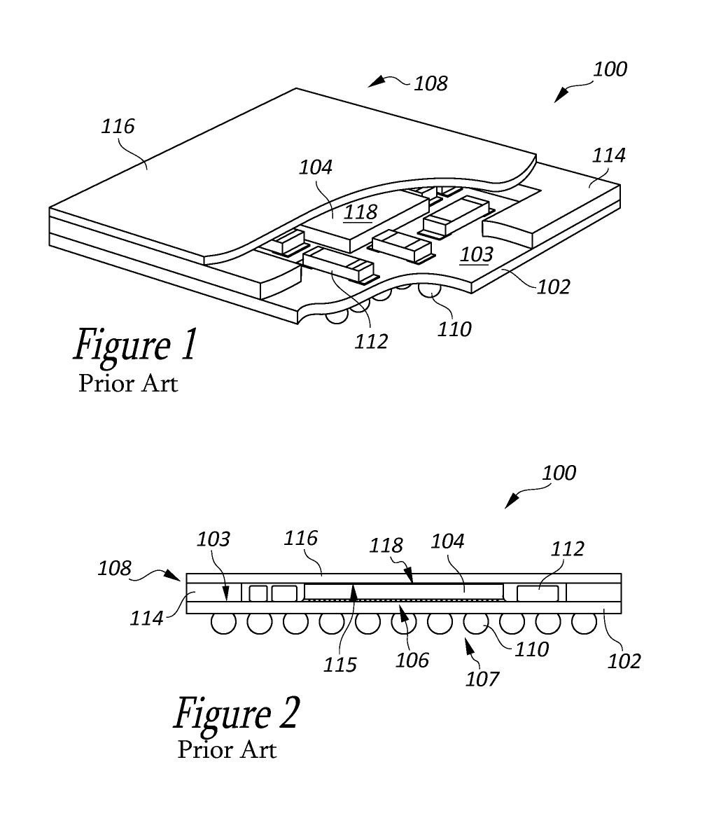

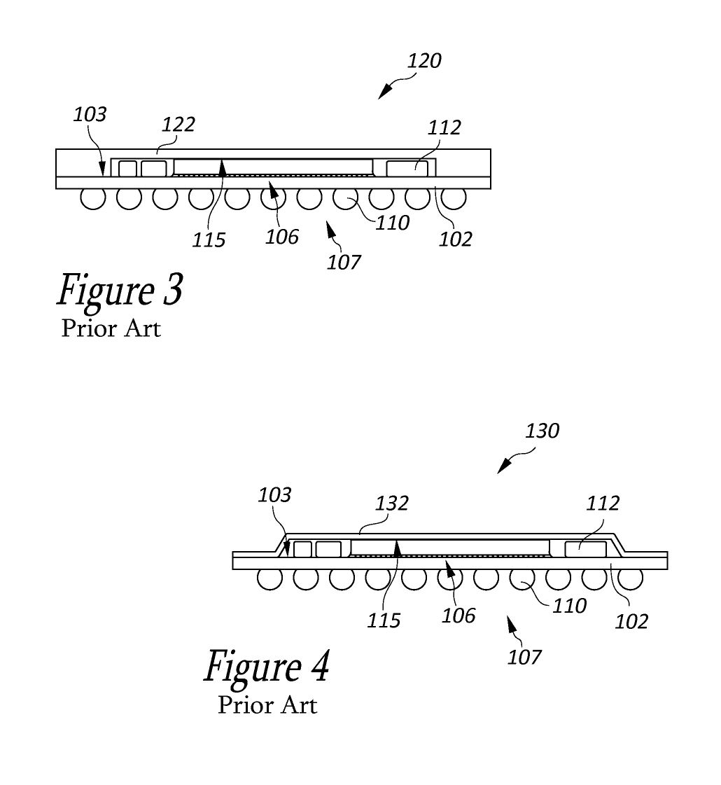

While the TEFCBGA packages described above with reference to FIGS. 1-4 provide significant advantages over conventional semiconductor packages, they are also prone to some disadvantages. In particular, because they rely on passive cooling, the semiconductor devices tend to operate at a higher average temperature than devices that operate within fan-cooled environments, or that have active cooling devices attached. This, in turn, can produce significant thermal mismatch between the semiconductor die and the laminate base, and between the laminate base and the underlying circuit board. It should be noted that the coefficient of thermal expansion (CTE) of silicon is about 2.5 ppm/° C., while that of a typical package laminate base is around 17 ppm/° C.

As temperature increases, the laminate undergoes greater linear expansion than the silicon die. As a result, the solder joints between the die and the laminate are subjected to significant shear stress, which can cause failure of the solder joints, particularly those nearest to the perimeter of the die. The likelihood of such failure increases over time, as the solder joints become fatigued by repeated thermal cycling. Additionally, the package undergoes distortion caused by the unequal expansion of the die and laminate. Because the laminate expands at a greater rate than the die, the outer edges of the laminate tend to curl upward from the center (toward the die), which produces tensile stress on the solder joints between the laminate and PCB, especially around the perimeter of the array, again resulting in potential failure of the solder joints, or delamination of the PCB.

The problems outlined above increase in direct relation to the size of the semiconductor die. Thus, as die size increases, the average reliability and working life of a given device decreases. This is a significant problem, in view of the fact that the current market trends toward miniaturization and increased functionality means that semiconductor device manufacturers are under pressure to incorporate more systems and functions into individual devices. The result is that size and circuit density of semiconductor devices are both increasing.

The undesirable effects of thermal mismatch in electronic components can be reduced by thinning the semiconductor die. A typical die is around 750 μm-1 mm in thickness, but dice can be thinned to a significant degree using various known chemical and manufacturing processes, in some case to as thin as around 50-200 μm. Thinning the die can significantly reduce the effects of thermal mismatch, including both strain and warpage, thereby increasing the reliability of the device and of the connection between the device and a circuit board.

However, with respect to the TEFCBGA packaging described in the background, thinning the die results in a gap between the back face of the die and the inner face of the heat spreader, which affects the transfer of heat from the die to the spreader. To compensate for the increased gap, a thicker layer of thermal interface material can be provided between the back face of the die and the heat spreader. However, most thermal interface materials have a lower value of thermal conductivity than materials commonly used for heat spreaders, so the thicker layer attenuates the transfer of heat from the die to the spreader. The result is that the average operating temperature of the die is increased, which can negatively affect the operation of the semiconductor device in well known ways, and also increases the thermal mismatch, which tends to cancel some of the benefits obtained by thinning the die.

One possible solution is to reduce the height of the heat spreader to eliminate the gap. However, if the clearance inside the heat spreader is reduced to the height of the thinned die, there is not sufficient space to receive the passive devices between the spreader and the laminate, so the advantages of mounting the passive devices inside the package are lost.

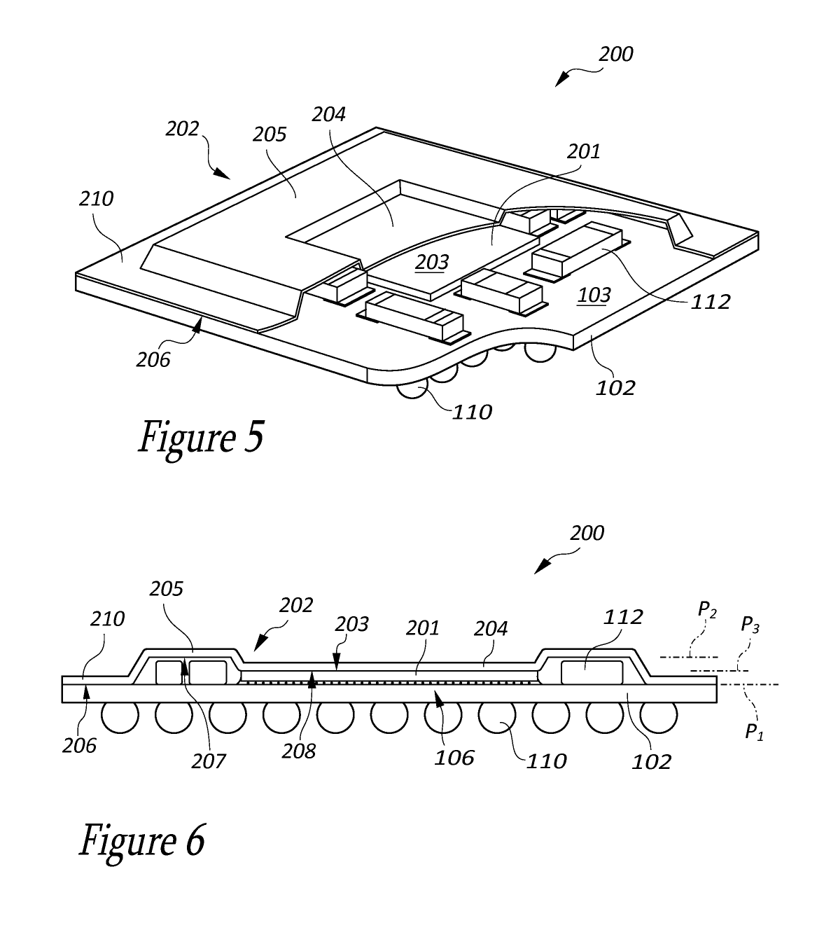

FIG. 5 is a partially cut-away perspective view of a TEFCBGA package 200, according to an embodiment, that overcomes many of the problems described above. FIG. 6 is a diagrammatical side view of the package 200.

The package 200 includes a laminate base 102, a thinned semiconductor die 201 mounted to the laminate base, and a hat-top-style heat spreader 202 mounted to the laminate base over the semiconductor die. The heat spreader 202 includes a rim 210 having a face 206 that extends fully around a perimeter of the spreader, and that lies in a first plane P₁, a web 205, and a projection 204. The rim 210 is coupled to the projection 204 by the web 205. The rim face 206 is sized and shaped to be adhered to the back face 103 of the laminate base 102 around its perimeter. An inner face 207 of the web 205 lies in a second plane P₂ that is separated from the first plane P₁ by a distance sufficient to provide clearance between the laminate base 102 and the inner face for the placement of passive devices 112 on the laminate base 102. The projection 204 includes a projection face 208 that lies in a third plane P₃ and that extends forward from the inner face 207 toward the laminate base 102 a distance sufficient to bring the projection face into close contact with a back surface 203 of the thinned semiconductor die 201. Lateral dimensions of the projection face 208 are preferably at least equal to lateral dimensions of the semiconductor die 201 so that the projection face is in direct contact with the die over the entire back surface 203. This provides the maximum possible surface area for transfer of heat from the die to the heat spreader 202.

The rim face 206 of the heat spreader 202 is coupled to the back face 103 of the laminate base 102 by any appropriate method, including adhesive, fasteners, solder, etc. For the purpose of this disclosure, it is assumed that a suitable adhesive is employed to couple the rim face 206 to the back face 103 of the laminate base 102. While such adhesive will typically constitute a very thin layer between the rim face 206 and the back face 103, it will have some thickness. Nevertheless, for the purpose of this disclosure, the rim face 206 and the back face 103 will be considered to be coplanar. Thus, a minimum distance between the first and second planes P₁, P₂ can be defined as being equal to the distance from the back face 103 of the laminate base 102 to the back-most point or surface of the tallest of the passive devices 112. At that distance, the inner face 207 will be in direct contact with that backmost point. One of ordinary skill in the art will recognize that in practice, the minimum distance can be reduced by an amount equal to any space introduced between the rim face 206 and the back face 103 by an adhesive or other fastening means.

Likewise, although a thermal interface material between the back face 203 of the die and the projection face 208 of the spreader is preferably as thin as possible, any thickness introduced will be ignored for the purpose of defining a spacing between the first plane P₁ and the third plane P₃. Thus, assuming passive devices 112 having thicknesses of no more than 1 mm and a thinned die 201 having a thickness, including the thickness of a BGA 106 coupling the die to the laminate 102, of 150 μm, the distance between the first plane P₁, and the second plane P₂ can be 1 mm or more. Given a spacing of 1 mm between P₁ and P₂, the spacing between the second plane P₂ and the third plane P₃ is 850 μm, so that the distance between the first and third planes is equal to the thickness of the die 203.

Because the inner surface 208 of the projection portion 204 is in close contact with the back surface 203 of the thinned semiconductor die 201, thermal transfer from the die to the heat spreader 202 is substantially equal to thermal transfer from the die 104 to the spreader 132 described above with reference to FIG. 4. However, because the semiconductor die 201 is substantially thinner than the die 104, thermal mismatch is significantly lower and the reliability of the package 200 is significantly higher, given otherwise equivalent configurations. Likewise, the reliability of a joint formed between the package 200 and a circuit board is also higher, relative to that of the package 130 and a circuit board.

The heat spreader 202 is manufactured from sheet metal in a stamping operation that is, except for the stamping dies used, substantially identical to the operation employed to manufacture the heat spreader 132 of FIG. 4. Manufacturing costs of the spreader 202 and assembly costs of the package 200 are likewise substantially identical to the corresponding costs associated with the spreader 132 and package 130 of FIG. 4.

Finally, the clearance space between the laminate base 102 and the inner surface 207 of the web 205 can be selected and manufactured to accommodate passive devices of different sizes and shapes, without regard for the thickness of the semiconductor die 201. This is not possible with the prior art heat spreaders; if the clearance were increased to accommodate a passive device that was thicker than the die, this would result in a separation between the die and the spreader, and would reduce heat transfer.

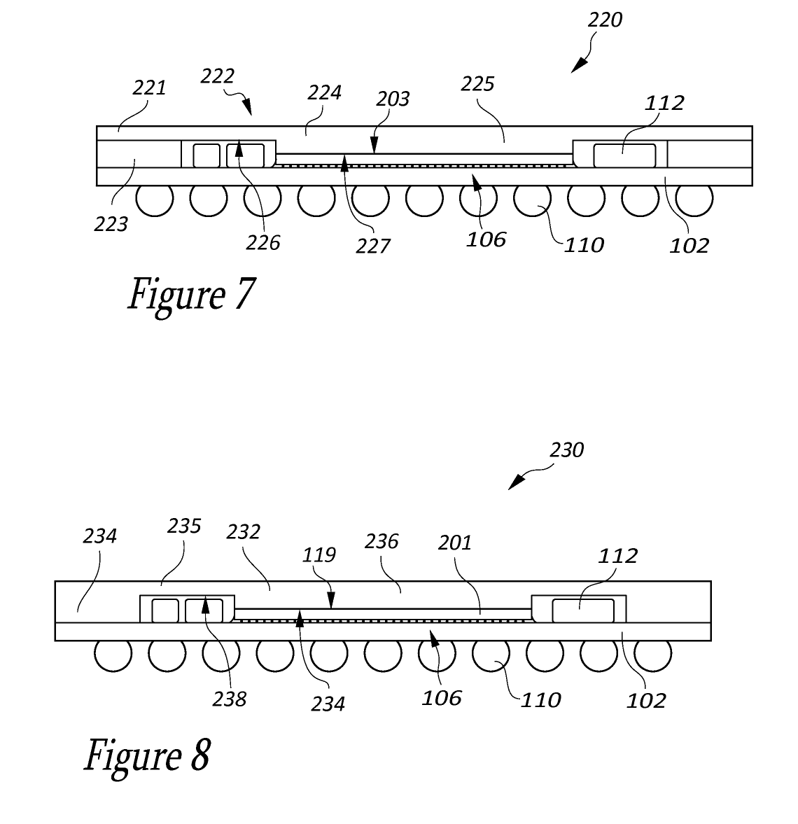

FIG. 7 is a diagrammatical side view of a TEFCBGA package 220 according to another embodiment. In many respects, package 220 is substantially similar to the package 200 of FIGS. 5 and 6. However, the package 220 employs a heat spreader 222 of a different design.

The heat spreader 222 comprises a stiffener 223 and a lid 224. The lid 224 includes a projection portion 225 and a flange 221. The projection portion 225 has a projection face 227 that is in close contact with the back face 203 of the semiconductor die 201. The flange 221 includes an inner face 226. The stiffener, acting as a rim, is attached to the base 102 on one side, and to the flange 221 of the lid 224 on the other side, by means of a suitable adhesive, or its equivalent. The flange 221 acts as a web to couple the stiffener 223 to the projection portion 225. A thickness of the stiffener 223 is selected to accommodate the thickness of the passive devices 112, while the distance the projection 225 extends inward from the inner face 226 is selected to permit close contact with the semiconductor die, given the thickness of the stiffener 223.

Operation of the heat spreader 222 is substantially identical to that of the heat spreader 204 described above with reference to FIGS. 5 and 6. The projection portion 225 of the heat spreader 222 makes contact with the back face 203 of the semiconductor die 201 while providing sufficient space for the passive devices to be positioned on the laminate base 102. This permits the use of a thinned die 201 to reduce the effects of thermal mismatch without reducing thermal transfer to the heat spreader or losing the benefits of mounting the passive devices inside the package 220. Manufacturing and assembly processes and costs are substantially identical to those of the heat spreader 108 and package 100 described with reference to FIGS. 1 and 2.

One advantage of the heat spreader 222 of FIG. 7 is that it can be adjusted after manufacture to accommodate semiconductor dice of varying thicknesses. Assuming ample clearance is provided for the passive devices, the heat spreader 222 can be modified to accommodate a thicker or thinner die by selecting a stiffener having a corresponding difference in thickness. Substantially standard lids can be manufactured with projections sized to accommodate semiconductor dice of different lateral dimensions, and stiffeners of various thicknesses can be manufactured to accommodate dice of different thicknesses. When assembling packages employing a particular size of die, the lids can be selected according to the lateral dimensions of the die, and the stiffeners according to its thickness.

FIG. 8 is a diagrammatical side view of a TEFCBGA package 230 according to another embodiment. The package 230 includes a heat spreader 232 that is similar in structure to the heat spreader 224 of FIG. 7, except that the spreader 232 is a single integrated element, where the spreader 224 has a separate stiffener. In other respects, the heat spreader 232 is substantially similar to the heat spreader 222 of FIG. 7, having a rim portion 234 with a thickness selected to accommodate passive devices 112. a web 235 coupling the rim portion to a projection portion 236, which extends inward from an inner face 238 of the web a distance selected to bring a projection face 240 into close contact with the back surface 203 of the thinned die 201. Thus, the heat spreader 230 provides advantages that are similar to those described with reference to the heat spreader 202 of FIGS. 5 and 6 without increasing manufacturing and assembly costs over those of the heat spreader 132 and package 130 described with reference to FIG. 4.

Embodiments are described as including passive devices positioned on a laminate base and covered by a heat spreader. According to other embodiments, active devices are also positioned on the laminate base. For example, according to an embodiment, a power transistor is positioned on the laminate base. A thickness of the power transistor and the spacing between first and second planes P₁ and P₂ are selected to be substantially equal, so that the inner face of the heat spreader contacts the transistor and acts also to conduct heat from the power transistor.

Devices that are formed on semiconductor material substrates—e.g., silicon wafers—are generally formed on only one surface thereof, and actually occupy a very small part of the total thickness of the substrate. This surface is generally referred to as the active, front, or top surface. Likewise, for the purposes of the present disclosure and claims, the terms front and back are used to establish an orientation with reference to a semiconductor wafer or die. For example, where a device includes a semiconductor die, reference to a front surface of some element of the device can be understood as referring to the surface of that element that would be uppermost if the device as a whole were oriented so that the active surface of the die was the uppermost part of the die. Of course, a back surface of an element is the surface that would be lowermost, given the same orientation of the device. Use of either term to refer to an element of such a device is not to be construed as indicating or requiring an actual physical orientation of the element, the device, or the associated semiconductor component, and, where used in a claim, does not limit the claim except as explained above.

In describing the embodiments illustrated in the drawings, directional references, such as right, left, upper, lower, etc., may be used to refer to elements or movements as they are shown in the figures. Such terms are used to simplify the description and are not to be construed as limiting the claims in any way.

Ordinal numbers, e.g., first, second, third, etc., are used in the claims and specification according to conventional practice, i.e., for the purpose of clearly distinguishing between claimed elements or features thereof. The use of such numbers does not suggest any other relationship, e.g., order of operation or relative position of such elements, nor does it exclude the possible combination of the listed elements into a single, multiple-function structure or housing. Furthermore, ordinal numbers used in the claims have no specific correspondence to those used in the specification to refer to elements of disclosed embodiments on which those claims read.

The term coupled, as used in the specification and claims, includes within its scope indirect coupling, such as when two elements are coupled with one or more intervening elements even where no intervening elements are recited. For example, where a claim recites a semiconductor die coupled to a package laminate, this language reads on embodiments in which the die is coupled via a plurality of solder balls or any other means, including other intervening structures.

The abstract of the disclosure is provided as a brief outline of some of the principles of the disclosure according to one embodiment, and is not intended as a complete or definitive description of any embodiment thereof, nor should it be relied upon to define terms used in the specification or claims. The abstract does not limit the scope of the claims.

Elements of the various embodiments described above can be combined, and further modifications can be made, to provide further embodiments without deviating from the spirit and scope of the disclosure.

These and other changes can be made to the embodiments in light of the above-detailed description. In general, in the following claims, the terms used should not be construed to limit the claims to the specific embodiments disclosed in the specification, but should be construed to include all possible embodiments along with the full scope of equivalents to which such claims are entitled. Accordingly, the claims are not limited by the disclosure.

1. A heat spreader, comprising:
a rim extending around a perimeter and having a face lying in a first plane;
a web coupled to the rim and having an inner face lying in a second plane that is spaced apart from and parallel to the first plane; and
a projection coupled by the web to the rim and having a projection face lying in a third plane between the first and second planes and parallel to the first and second planes.

2. The heat spreader of claim 1 wherein the an inner face extends in the second plane.

3. The heat spreader of claim 1 wherein the heat spreader is sheet metal shaped to define the rim, the web, and the projection.

4. The spreader of claim 1, comprising:
a stiffener having first and second faces and serving as the rim, the first face of the stiffener defining the rim face; and
a lid including a flange serving as the web, the projection extending from an inner face of the flange, the stiffener being coupled to the inner face of the lid.

5. A semiconductor package, comprising:
a laminate base;
a semiconductor die coupled to a first face of the laminate base; and
a heat spreader coupled to the first face of the laminate base and completely enclosing the semiconductor die, the heat spreader having:
a rim with a rim face coupled to the first face of the laminate base around a perimeter thereof,
a web coupled to the rim and having an inner face spaced apart from the first face of the laminate base, and
a projection extending from the inner face of the web toward the laminate base and having a projection face in close thermal contact with a face of the semiconductor die.

6. The package of claim 5, comprising an additional device coupled to the first face of the laminate base and enclosed by the heat spreader between the semiconductor die and the rim, and having a thickness that is greater than a thickness of the semiconductor die.

7. The package of claim 6 wherein the additional device is a passive device electrically coupled to the semiconductor die.

8. The package of claim 5 wherein the semiconductor die is coupled to the first face of the laminate base by a plurality of solder joints, in a flip-chip configuration.

9. The package of claim 5 wherein the laminate base includes a ball grid array on a second face, opposite the first face.

10. The package of claim 5 wherein the heat sink is sheet metal formed to define the rim, the web, and the projection.

11. The package of claim 5 wherein the heat sink includes a stiffener, having a front face on which the rim face is defined, and a lid, which comprises the web and the projection, and to which the stiffener is coupled.

12. The package of claim 5 wherein the rim face defines a first plane and the projection face defines a second plane, parallel to the first plane, a first distance, from the first plane to the second plane, being substantially equal to a second distance, from a plane defined by the first face of the laminate base to a plane defined by the face of the semiconductor die, and wherein a third distance, from the first plane to the inner face of the web, is greater than the either of the first or second distances.

13. The package of claim 12 wherein the first distance is less than about 500 μm.

14. The package of claim 12 wherein the first distance is less than about 200 μm.

15. The package of claim 5 wherein dimensions of the projection face are at least equal to corresponding dimensions of the face of the semiconductor die with which the projection face is in close thermal contact.

16. A method, comprising:
forming a heat sink from a thermally conductive material, including:
forming a rim around a perimeter of the heat sink, a face of the rim defining a first plane;
defining within the rim a web having an inner face spaced apart from the first plane; and
forming a projection coupled by the web to the rim and extending from the inner face toward the first plane, a projection face of the projection lying in a second plane that is between the first plane and the inner face and parallel to the first plane.

17. The method of claim 16 comprising providing a distance between the first plane and the second face of less than about 500 μm.

18. The method of claim 16 comprising providing a distance between the first plane and the second face of less than about 200 μm.

19. The method of claim 16 wherein forming the heat sink comprises defining the rim, web, and projection in sheet metal, using a stamping operation.

20. The method of claim 16 wherein forming the heat sink comprises machining the rim, web, and projection from a metal blank.
